(19) United States
(12) Patent Application Publication
(10) Pub. No.: US 2026/0282454 A1
(43) Pub. Date: Sep. 17, 2026

(54) THIN-FILM TRANSISTOR SUBSTRATE

(71) Applicant: InnoLux Corporation, Miao-Li County (TW)

(72) Inventors: Han-Tsung SU, Miao-Li County (TW); Jhe-Ciou JHU, Miao-Li County (TW); Te-Yi CHEN, Miao-Li County (TW)

(73) Assignee: InnoLux Corporation, Miao-Li County (TW)

(21) Appl. No.: 19/538,927

(22) Filed: Feb. 12, 2026

(30) Foreign Application Priority Data
Mar. 13, 2025 (CN) 202510293474.8

(51) Int. Cl. H10D 30/67; H10D 86/40

(52) U.S. Cl. CPC H10D 30/6757; H10D 86/423; H10D 86/441

(57) ABSTRACT

A thin-film transistor substrate includes a substrate, a first gate electrode, and a semiconductor layer. The first gate electrode is disposed on the substrate and includes a first side surface. The semiconductor layer is disposed on the first gate electrode and includes an active region, and the active region includes a second side surface. The second side surface is located adjacent to the first side surface, and a first distance between the first side surface and the second side surface is less than 0.5 micrometer.

### BACKGROUND OF THE DISCLOSURE

### 1. Field of the Disclosure

The present disclosure relates to a semiconductor device, and more particularly, to a thin-film transistor substrate.

### 2. Description of the Prior Art

Thin-film transistors are used in electronic devices (such as displays, X-ray sensors, etc.) for providing voltage or current switching. Based on the material of the semiconductor layer in the thin-film transistor, thin-film transistors may be divided into several types, such as amorphous silicon thin-film transistors (a-Si TFT), polycrystalline silicon thin-film transistors (poly silicon TFT), and oxide semiconductor thin-film transistors (oxide semiconductor TFT). Oxide semiconductor thin film-transistors have become a very important thin-film transistor technology at present because of performance advantages such as high electron mobility, low leakage current, and relatively simple process.

### SUMMARY OF THE DISCLOSURE

It is one of the objectives of the present disclosure to provide a thin-film transistor substrate. A distance between a side surface of an active region in a semiconductor layer and a side surface of a gate electrode is controlled for reducing parasitic capacitance and improving operation performance.

A thin-film transistor substrate is provided in this disclosure. The thin-film transistor substrate includes a substrate, a first gate electrode, and a semiconductor layer. The first gate electrode is disposed on the substrate and includes a first side surface. The semiconductor layer is disposed on the first gate electrode and includes an active region, and the active region includes a second side surface. The second side surface is located adjacent to the first side surface, and a first distance between the first side surface and the second side surface is less than 0.5 micrometer.

These and other objectives of the present disclosure will no doubt become obvious to those of ordinary skill in the art after reading the following detailed description of the embodiment that is illustrated in the various figures and drawings.

### BRIEF DESCRIPTION OF THE DRAWINGS

FIG. 1 is a schematic diagram of a thin-film transistor substrate according to a first embodiment of the present disclosure.

FIG. 2 is a schematic diagram of a thin-film transistor substrate according to a second embodiment of the present disclosure.

FIG. 3 is a schematic diagram of a thin-film transistor substrate according to a third embodiment of the present disclosure.

FIG. 4 is a schematic diagram of a thin-film transistor substrate according to a fourth embodiment of the present disclosure.

FIG. 5 is a schematic diagram of a thin-film transistor substrate according to a fifth embodiment of the present disclosure.

FIG. 6 is a schematic flow chart of a manufacturing method of a thin-film transistor substrate according to an embodiment of the present disclosure.

FIG. 7 is a schematic diagram illustrating a doping process according to an embodiment of the present disclosure.

FIG. 8 is a schematic diagram illustrating an exposure process according to an embodiment of the present disclosure.

FIG. 9 is a schematic diagram illustrating an exposure process according to an embodiment of the present disclosure.

FIG. 10 is a schematic diagram illustrating an exposure process according to an embodiment of the present disclosure.

### DETAILED DESCRIPTION

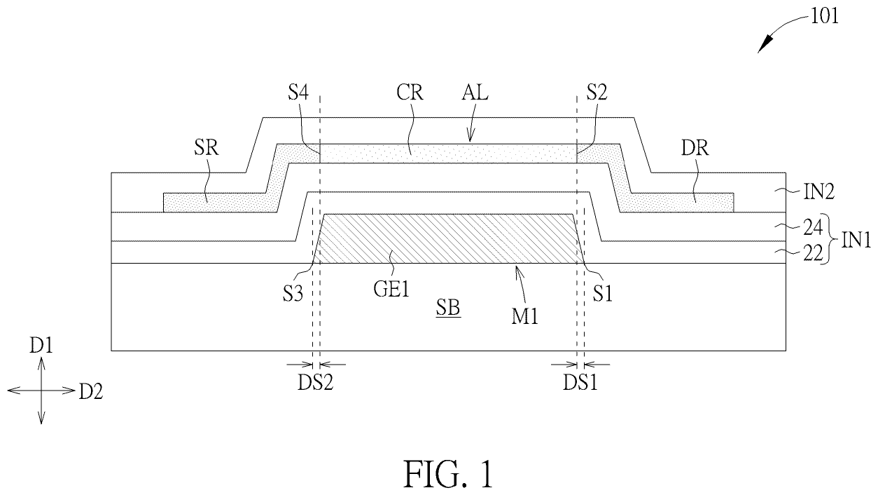

Please refer to FIG. 1. FIG. 1 is a schematic diagram of a thin-film transistor substrate 101 according to a first embodiment of the present disclosure. The thin-film transistor substrate 101 includes a substrate SB, a first gate electrode GE1, and a semiconductor layer AL. The first gate electrode GE1 is disposed on the substrate SB and includes a first side surface S1. The semiconductor layer AL is disposed on the first gate electrode GE1 and includes an active region CR, and the active region CR includes a second side surface S2. The second side surface S2 is located adjacent to the first side surface S1, and a first distance DS1 between the first side surface S1 and the second side surface S2 is less than 0.5 micrometer. In some embodiments, the first gate electrode GE1 may further include a third side surface S3 opposite to the first side surface S1, the active region CR may further include a fourth side surface S4 opposite to the second side surface S2. A second distance DS2 between the third side surface S3 and the fourth side surface S4 is less than 0.5 micrometer, and a difference between the first distance DS1 and the second distance DS2 may be less than 0.5 micrometer, but not limited thereto. A vertical direction D1 may be regarded as a thickness direction of the substrate SB, the second side surface S2 and the fourth side surface S4 may be regarded as two side surfaces of the active region CR opposite to each other in a horizontal direction D2 orthogonal to the vertical direction D1, and the first side surface S1 and the third side surface S3 may be regarded as two side surfaces of the first gate electrode GE1 opposite to each other in the horizontal direction D2. In some embodiments, because of the influence of related process characteristics (such as characteristics of etching processes, but not limited thereto), the side surface of the first gate electrode GE1 may be an inclined side surface, the first distance DS1 between the first side surface S1 and the second side surface S2 described above may be a horizontal distance between the bottom of the first side surface S1 and the bottom of the second surface S2, and the second distance DS2 between the third side surface S3 and the fourth side surface S4 described above may be a horizontal distance between the bottom of the third side surface S3 and the bottom of the fourth surface S4, but not limited thereto. In some embodiments, the semiconductor layer AL may further include a source region SR and a drain region DR located at two opposite sides of the active region CR, respectively, and the source region SR and the drain region DR are connected with the active region CR. The second side surface S2 may be directly connected with the drain region DR, and the fourth side surface S4 may be directly connected with the source region SR. In some embodiments, the first gate electrode GE1 may be used as a mask for performing an exposure process to a photoresist layer formed above the semiconductor layer AL from a side of the substrate SB facing away from the first gate electrode GE1 (such as a back side) and a corresponding developing process may be performed for forming a patterned photoresist layer. Subsequently, a treatment (such as a doping process, but not limited thereto) using the patterned photoresist layer as a mask may be performed to the semiconductor layer AL for forming the source region SR and the drain region DR, the side surfaces of the active region CR and the side surfaces of the first gate electrode GE1 may be substantially aligned with one another in a self-aligning manner accordingly, and the parasitic capacitance between the first gate electrode GE1 and the source region SR and the parasitic capacitance between the first gate electrode GE1 and the drain region DR may be reduced accordingly for improving the operation performance. In some embodiments, the first side surface S1 may overlap the second side surface S2 when viewed in the vertical direction D1, and the third side surface S3 may overlap the fourth side surface S4 when viewed in the vertical direction D1, but not limited thereto.

In some embodiments, the thin-film transistor substrate 101 may further include an insulation layer IN1 and an insulation layer IN2. The insulation layer IN1 may be disposed on the substrate SB and cover the first electrode GE1, the semiconductor layer AL may be disposed on the insulation layer IN1, and the insulation layer IN2 may be disposed on the semiconductor layer AL and the insulation layer IN1. A part of the insulation layer IN1 may be located between the first gate electrode GE1 and the semiconductor layer AL, and the insulation layer IN1 may include a single layer or multiple layers of insulation materials. For example, in some embodiments, the insulation layer IN1 may include a first layer 22 and a second layer 24 disposed on the first layer 22, and a material composition of the second layer 24 may be different from a material composition of the first layer 22. For instance, the first layer 22 and the second layer 24 may include silicon nitride (SiNₓ) and silicon oxide (SiOₓ), respectively, but not limited thereto. The insulation layer IN2 may include an organic insulation material or an inorganic insulation material, such as silicon nitride, silicon oxide, silicon oxynitride (SiNₓO_{y}), polyimide (PI), polyester, other suitable materials, or a combination of the materials described above. The substrate SB may include a rigid material or a flexible material. It should be noted that, in some embodiments, the substrate SB may include a multiple layer structure and is not limited to the structure illustrated in FIG. 1. In addition, the first gate structure GE1 may be at least a part of an electrically conductive layer M1, and the electrically conductive layer M1 may include any suitable electrically conductive materials, such as but not limited to a metallic electrically conductive material.

The semiconductor layer AL may include low temperature polysilicon semiconductor or amorphous silicon (a-Si) semiconductor, the metal oxide semiconductor material may include but is not limited to indium gallium zinc oxide (IGZO). In this embodiment, the semiconductor layer AL includes a metal oxide semiconductor material as an example. In some embodiments, the source region SR and the drain region DR may be regions having relatively higher carrier concentration and formed in the semiconductor layer by a suitable treatment (such as a doping process, but not limited thereto), the carrier concentration (such as an oxygen vacancy concentration, but not limited thereto) in the source region SR and the drain region DR may be higher than the carrier concentration in the active region CR accordingly, and the carrier concentration in the source region SR and the drain region DR may be increased by the doping process or other suitable approaches, but not limited thereto. Additionally, in some embodiments, the semiconductor layer AL may be measured by scanning capacitance microscopy (SCM), the measurement results (such as a capacitance vs. voltage relationship curve (C-V curve) and/or a distribution image of a ratio of the change in capacitance to the change in voltage (dC/dV), but not limited thereto) may be used to determine the region with high carrier concentration and the region with low carrier concentration, and the positions of the interface between the active region CR and the source region SR in the semiconductor layer AL (i.e. the fourth side surface S4) and the interface between the active region CR and the drain region DR in the semiconductor layer LA (i.e. the second side surface S2) may be obtained accordingly.

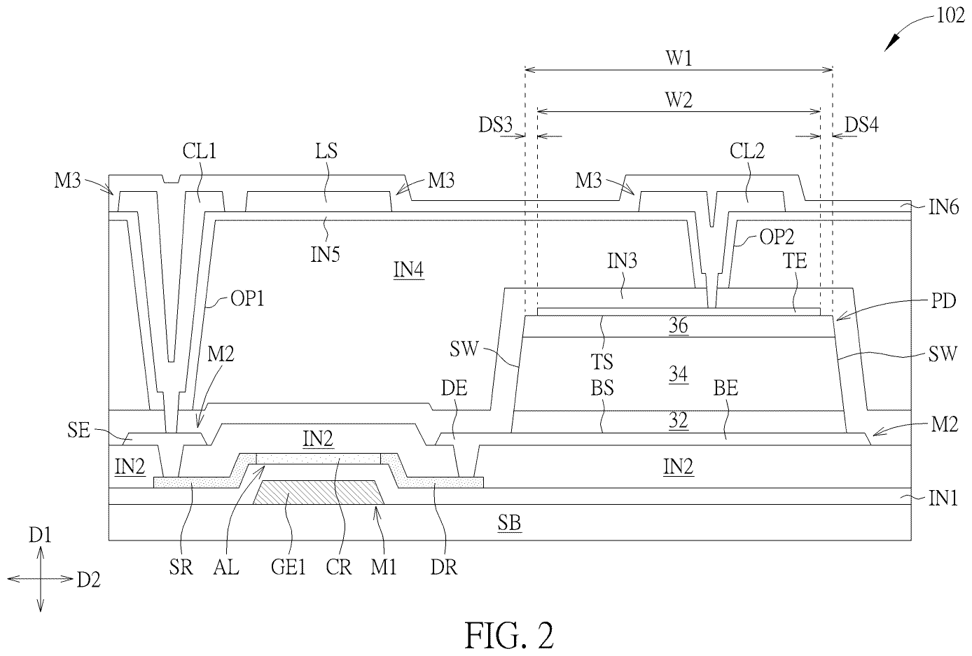

FIG. 2 is a schematic diagram of a thin-film transistor substrate 102 according to a second embodiment of the present disclosure. As shown in FIG. 2, the thin-film transistor substrate 102 may further include a source electrode SE, a drain electrode DE, and a light-sensing element PD. The source electrode SE, the drain electrode DE, and the light-sensing element PD are disposed on the substrate SB, and the light-sensing element PD is electrically connected with the drain electrode DE. In some embodiments, the thin-film transistor substrate 102 may include an electrically conductive layer M2, the electrically conductive layer M2 may include any suitable electrically conductive material, such as a metallic electrically material, but not limited thereto, and the source electrode SE and the drain electrode DE may be a part of the electrically conductive layer M2, respectively. A part of the source electrode SE may be disposed on the insulation layer IN2 and a part of the source electrode SE may penetrate through the insulation layer IN2 located above the source region SR for contacting and being electrically connected with the source region SR. A part of the drain electrode DE may be disposed on the insulation layer IN2 and a part of the drain electrode DE may penetrate through the insulation layer IN2 located above the drain region DR for contacting and being electrically connected with the drain region DR. In some embodiments, a part of the electrically conductive layer M2 may be disposed under the light-sensing element PD in the vertical direction D1, the electrically conductive layer M2 disposed under the light-sensing element PD may be regarded as a bottom electrode BE, the bottom electrode BE may be directly connected with the drain electrode DE, and the drain electrode DE may be electrically connected with the light-sensing element PD via the bottom electrode BE, but not limited thereto.

In some embodiments, the light-sensing element PD may include a first semiconductor layer 32, a second semiconductor layer 34, and a third semiconductor layer 36 disposed and stacked with one another. The first semiconductor layer 32 is located between the bottom electrode BE and the second semiconductor layer 34 in the vertical direction D1, the second semiconductor layer 34 is located between the first semiconductor layer 32 and the third semiconductor layer 36 in the vertical direction D1, and the first semiconductor layer 32 may directly contact the bottom electrode BE, but not limited thereto. In some embodiments, the second semiconductor layer 34 may include an intrinsic semiconductor layer, and the first semiconductor layer 32 and the third semiconductor layer 36 may respectively include a p-type semiconductor layer or an n-type semiconductor layer. For example, the third semiconductor layer 36 may be an n-type semiconductor layer when the first semiconductor layer 32 is a p-type semiconductor layer, and the third semiconductor layer 36 may be a p-type semiconductor layer when the first semiconductor layer 32 is an n-type semiconductor layer. Therefore, the n-type semiconductor layer or the p-type semiconductor layer in the light-sensing element PD may directly contact electrically conductive layer M2, but not limited thereto. In addition, the material of the intrinsic semiconductor layer may include intrinsic amorphous silicon, the material of the n-type semiconductor layer may include n-type doped amorphous silicon, and the material of the p-type semiconductor layer may include p-type doped amorphous silicon, but not limited thereto.

In some embodiments, the thin-film transistor substrate 102 may further include a transparent electrically conductive layer TE disposed on the light-sensing element PD, and the transparent electrically conductive layer TE may be regarded as a top electrode of the light-sensing element PD located corresponding to the transparent electrically conductive layer TE, but not limited thereto. In some embodiments, a width W2 of the transparent electrically conductive layer TE may be less than a width W1 of the light-sensing element PD for reducing leakage current at the edge and improving related operation performance of the light-sensing element PD, but not limited thereto. The width W2 of the transparent electrically conductive layer TE may be regarded as a length of the transparent electrically conductive layer TE in a horizontal direction (such as the horizontal direction D2, but not limited thereto), and the width W1 of the light-sensing element PD may be regarded as a length of a top surface TS of the light-sensing element PD in a horizontal direction (such as the horizontal direction D2, but not limited thereto). The transparent electrically conductive layer TE may directly contact the top surface TS of the light-sensing element PD, but the edge of the top surface TS of the light-sensing element may be not covered by the transparent electrically conductive layer TE. For example, a distance between an edge of the transparent electrically conductive layer TE and an edge of the light-sensing element PD (such as an edge of the top surface TS) located corresponding to the transparent electrically conductive layer TE (such as a distance DS3 and a distance DS4) may range from 0.5 micrometer to 1.5 micrometers, but not limited thereto. Additionally, in some embodiments, an oxygen supplementation process may be performed to a lateral surface SW of the light-sensing element PD after the process of forming the light-sensing element PD for compensating negative influence of the process of forming the light-sensing element PD on the lateral surface SW (such as etching damage generated by an etching process to the side surface SW, but not limited thereto). Therefore, an oxygen concentration at the lateral surface SW of the light-sensing element PD may be higher than an oxygen concentration at the top surface TS of the light-sensing element PD and an oxygen concentration at a bottom surface BS of the light-sensing element PD, respectively, but not limited thereto.

In some embodiments, the thin-film transistor substrate 102 may further include a protection layer IN3, a protection layer IN4, a protection layer IN5, a protection layer IN6, and an electrically conductive layer M3 disposed on the substrate SB. The protection layer IN3 may cover the light-sensing element PD, the transparent electrically conductive layer TE, the source electrode SE, the drain electrode DE, and the insulation layer IN2. The protection layer IN4 is disposed on the protection layer IN3 and covers the light-sensing element PD, the transparent electrically conductive layer TE, the source electrode SE, and the drain electrode DE. An opening OP1 and an opening OP2 are located above the source electrode SE and the transparent electrically conductive layer TE, respectively. The opening OP1 and the opening OP2 penetrate through the protection layer IN3 and the protection layer IN4 for being connected with and contacting the source electrode SE and the transparent electrically conductive layer TE, respectively. The protection layer IN5 may be partly located on the protection layer IN4 and partly located in the opening OP1 and the opening OP2. The electrically conductive layer M3 may include an electrically conductive layer CL1 and an electrically conductive layer CL2. The electrically conductive layer CL1 may be partly located on the protection layer IN5 and partly located in the opening OP1, and the electrically conductive layer CL1 may penetrate through the protection layer IN5, the protection layer IN4, and the protection layer IN3 for contacting and being electrically connected with the source electrode SE. The electrically conductive layer CL2 may be partly located on the protection layer IN5 and partly located in the opening OP2, and the electrically conductive layer CL2 may penetrate through the protection layer IN5, the protection layer IN4, and the protection layer IN3 for contacting and being electrically connected with the transparent electrically conductive layer TE. In some embodiments, the electrically conductive layer M3 may further include a shielding pattern LS disposed on the protection layer IN5 and disposed corresponding to the active region CR in the vertical direction D1 for providing light-shielding effect to the active region CR, but not limited thereto. The protection layer IN6 may be disposed on the protection layer IN5 and cover the electrically conductive layer M3, and the protection layer IN6 may be partly disposed in the opening OP1, but not limited thereto. The electrically conductive layer M3 may include any suitable electrically conductive material, such as a metallic electrically conductive material, but not limited thereto. The protection layer IN3, the protection layer IN5, and the protection layer IN6 may include silicon nitride, silicon oxide, silicon oxynitride, polyimide, polyester, other suitable materials, or a combination of the materials described above. The protection layer IN4 may include perfluoroalkoxy resin (PFA), but not limited thereto. It is worth noting that, the thin-film transistor substrate in this embodiment may be applied in a light-sensing device for the required low parasitic capacitance between the gate electrode and the source electrode in the light-sensing device and the required low parasitic capacitance between the gate electrode and the drain electrode in the light-sensing device, but the thin-film transistor substrate in this disclosure is not limited to be applied in the light-sensing device and may be applied in other types of devices according to the design considerations.

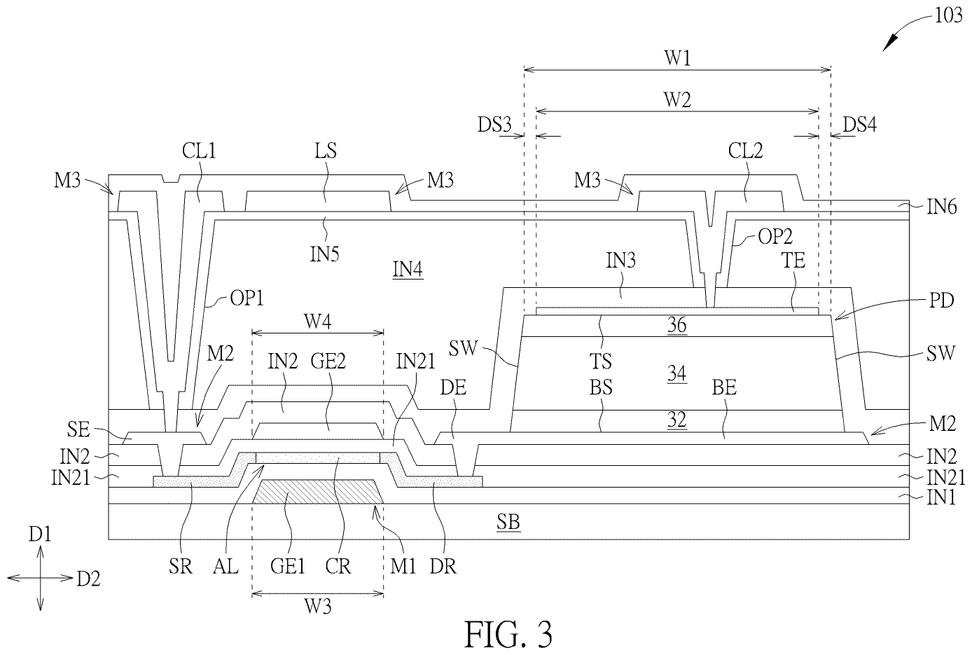

FIG. 3 is a schematic diagram of a thin-film transistor substrate 103 according to a third embodiment of the present disclosure. As shown in FIG. 3, the thin-film transistor substrate 103 further includes a second gate electrode GE2 and an insulation layer IN21. The second gate electrode GE2 may be disposed on the semiconductor layer AL, and the insulation layer IN21 may be disposed between the semiconductor layer AL and the second gate electrode GE2. The insulation layer IN21 may cover the insulation layer IN1 and the semiconductor layer AL, and the second gate electrode GE2 may be disposed on the insulation layer IN21. The insulation layer IN2 may be disposed on the second gate electrode GE2 and the insulation layer IN21, and the source electrode SE and the drain electrode DE may be partly disposed on the insulation layer IN2. The source electrode SE may penetrate through the insulation layer IN2 and the insulation layer IN21 for being electrically connected with the source region SR, and the drain electrode DE may penetrate through the insulation layer IN2 and the insulation layer IN21 for being electrically connected with the drain region DR. The insulation layer IN21 may include silicon oxide or other suitable insulation materials, and the second gate electrode GE2 may include any suitable electrically conductive material, such as a metallic electrically conductive material or a transparent electrically conductive material. In some embodiments, a width W3 of the first gate electrode GE1 may be substantially equal to a width W4 of the second gate electrode GE2, and the width W3 and the width W4 may be regarded as a length of the first gate electrode GE1 in the horizontal direction (such as the horizontal direction D2, but not limited thereto) and a length of the second gate electrode GE2 in the horizontal direction (such as the horizontal direction D2, but not limited thereto), respectively, but not limited thereto. In some embodiments, the width W3 of the first gate electrode GE1 may be substantially equal to the width W4 of the second gate electrode GE2 by a back side exposure process, and the material of the second gate electrode GE2 may be a transparent electrically conductive material, but not limited thereto.

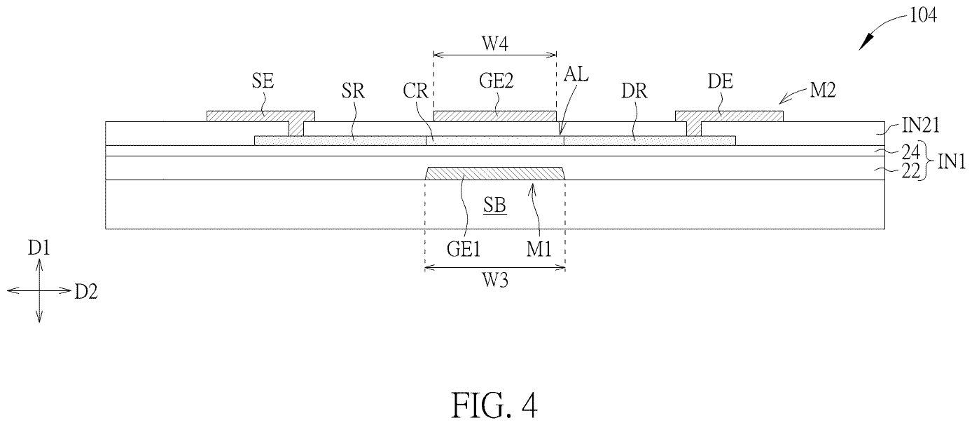

FIG. 4 is a schematic diagram of a thin-film transistor substrate 104 according to a fourth embodiment of the present disclosure. As shown in FIG. 4, in the thin-film transistor substrate 104, a part of the source electrode SE, a part of the drain electrode DE, and the second gate electrode GE2 may be disposed on the insulation layer IN21, the source electrode SE may penetrate through the insulation layer IN21 and be electrically connected with the source region SR, and the drain electrode DE may penetrate through the insulation layer IN21 and be electrically connected with the drain region DR. The source electrode SE and the drain electrode DE may be different portions of the electrically conductive layer M2 and have the same material composition, and the second gate electrode GE2, the source electrode SE, and the drain electrode DE may be regarded as being disposed at the same level. In some embodiments, the material of the second gate electrode GE2 may be different from that of the source electrode SE and the drain electrode. For example, the material of the second gate electrode GE2 may be a transparent electrically conductive layer, and the material of the source electrode SE and the drain electrode DE may be titanium, aluminum, molybdenum, or a combination thereof, but not limited thereto. In addition, a bottom surface of the second gate electrode GE2 disposed above the insulation layer IN21, a bottom surface of the source electrode SE disposed above the insulation layer IN21, and a bottom surface of the drain electrode DE disposed above the insulation layer IN21 may be substantially coplanar, but not limited thereto. In the manufacturing method of the thin-film transistor substrate 104 according to this embodiment, a second gate material layer (not illustrated) may be formed after the step of forming the insulation layer IN21. An exposure process using the first gate electrode GE1 as a mask may be performed to a photoresist layer formed above the second gate material layer from a side of the substrate SB away from the first gate electrode GE1 (such as a back side of the substrate SB), and a corresponding developing process may then be carried out for forming a patterned photoresist layer. Subsequently, the patterned photoresist layer is used as a mask in an etching process performed to the second gate material layer for forming the second gate electrode GE2, and a doping process is performed to the semiconductor layer AL with the patterned photoresist layer remaining on the second gate electrode GE2 for forming the source region SR and the drain region DR. Subsequently, the patterned photoresist layer described above may be removed, the openings corresponding to the source electrode SE and the drain electrode DE may be formed in the insulation layer IN21, and the source electrode SE and the drain electrode DE may then be formed. The source electrode SE and the drain electrode DE may be formed concurrently by performing a patterning process to an electrically conductive material formed on the insulation layer IN21, but not limited thereto.

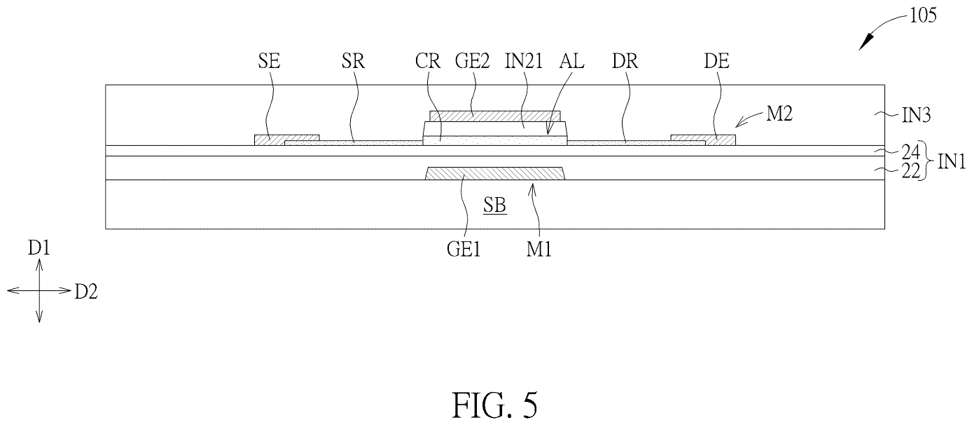

FIG. 5 is a schematic diagram of a thin-film transistor substrate 105 according to a fifth embodiment of the present disclosure. As shown in FIG. 5, in the thin-film transistor substrate 105, the semiconductor layer AL is disposed on the insulation layer IN1, and the source electrode SE and the drain electrode DE are disposed on the insulation layer IN1 and cover a portion of the source region SR and a portion of the drain region DR, respectively. The insulation layer IN21 is disposed between the active region CR and the second gate electrode GE2 in the vertical direction D1, and the second gate electrode GE2 and the insulation layer IN21 may be disposed corresponding to each other in the vertical direction D1 and have substantially the same pattern in the vertical direction D1 and/or substantially the same area in the vertical direction D1, but not limited thereto. In the manufacturing method of the thin-film transistor substrate 105 according to this embodiment, after the insulation material for forming the insulation layer IN21 is formed on the substrate SB, an exposure process using the first gate electrode GE1 as a mask may be performed to a photoresist layer formed above the semiconductor layer AL from a side of the substrate SB away from the first gate electrode GE1 (such as a back side of the substrate SB), and a corresponding developing process may then be carried out for forming a patterned photoresist layer. Subsequently, the patterned photoresist layer is used as a mask in a treatment (such as a doping process, but not limited thereto) performed to the semiconductor layer AL for forming the source region SR and the drain region DR. After the source region SR and the drain region DR are formed, the patterned photoresist layer described above may be used as a mask again in an etching process performed to the insulation material described above for forming the insulation layer IN21. In some embodiments, because of the influence of the etching process for forming the insulation layer IN21, the thickness of the source region SR and the thickness of the drain region DR may be slightly less than the thickness of the active region CR, respectively, but not limited thereto. After the step of forming the insulation layer IN21, the source electrode SE, the drain electrode DE, and the second gate electrode GE2 may be formed. The source electrode SE, the drain electrode DE, and the second gate electrode GE2 may be formed concurrently by performing a patterning process to an electrically conductive material formed on the insulation layer IN21, the semiconductor layer AL, and the insulation layer IN1, but not limited thereto. After the step of forming the source electrode SE, the drain electrode DE, and the second gate electrode GE2, the insulation layer IN3 may be formed covering the source electrode SE, the drain electrode DE, the second gate electrode GE2, the insulation layer IN21, the semiconductor layer AL, and the insulation layer IN1.

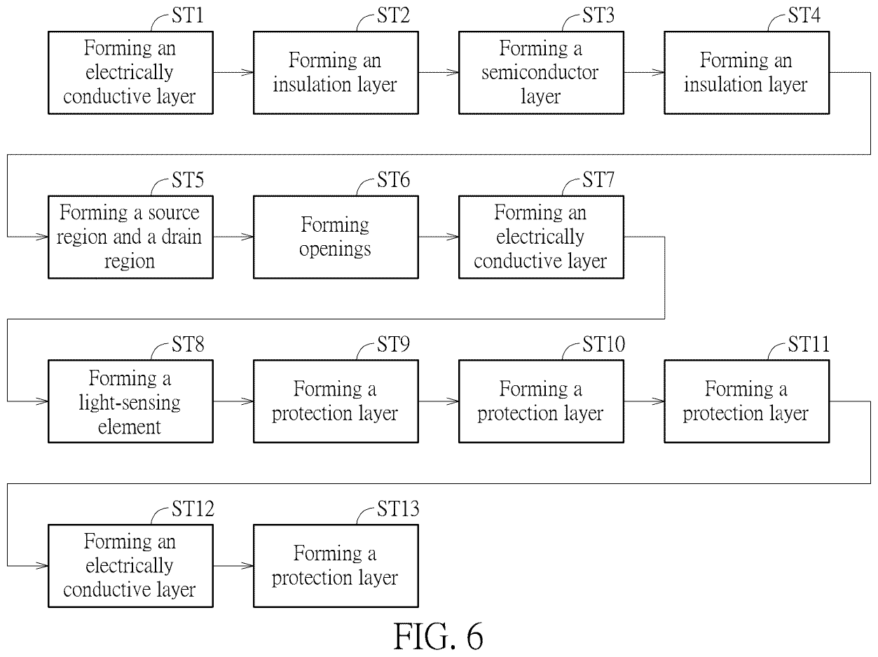

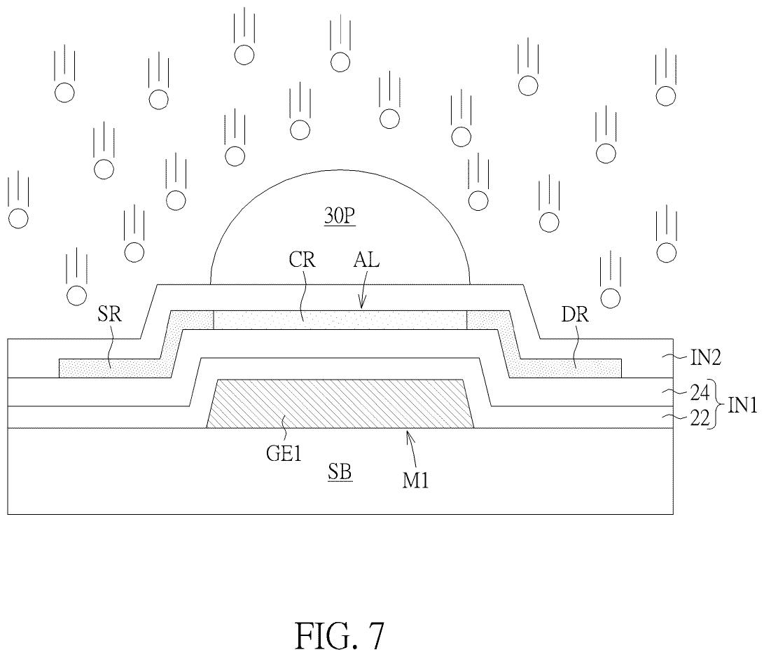

FIG. 6 is a schematic flow chart of a manufacturing method of a thin-film transistor substrate according to an embodiment of the present disclosure, and FIG. 7 is a schematic diagram illustrating a doping process according to an embodiment of the present disclosure. As shown in FIGS. 2, 6, and 7, in some embodiments, the manufacturing method of the thin-film transistor substrate in this disclosure may include but is not limited to the following steps. Firstly, the substrate SB is provided, the step ST1 may be carried out for forming the electrically conductive layer M1 on the substrate SB, and the electrically conductive layer M1 may include the first gate electrode GE1. In some embodiments, an electrically conductive material may be formed on the substrate SB by a film formation process, a photolithography and etching process may be performed to this electrically conductive material, and the electrically conductive material may be patterned to be the electrically conductive layer M1 via the photolithography and etching process, but not limited thereto. Subsequently, the step ST2 may be carried out for forming the insulation layer IN1 covering the substrate SB and the electrically conductive layer M1. The step ST3 may then be carried out for forming the semiconductor layer AL on the insulation layer IN1. In some embodiments, a semiconductor material may be formed on the insulation layer IN1 by a film formation process, a photolithography and etching process may be performed to this semiconductor material, and the semiconductor material may be patterned to be the semiconductor layer AL via the photolithography and etching process, but not limited thereto. Subsequently, the step ST4 may be carried out for forming the insulation layer IN2 covering the semiconductor layer AL and the insulation layer IN1. The step ST5 may then be carried out for forming the source region SR and the drain region DR in the semiconductor layer AL.

In some embodiments, after the step of forming the insulation layer IN2, a photoresist layer may be formed on the insulation layer IN2, an exposure process using the first gate electrode GE1 as a mask may be performed to the photoresist layer from a side of the substrate SB away from the first gate electrode GE1 (such as a back side of the substrate SB), and a corresponding developing process may then be carried out for forming a patterned photoresist layer 30P. Subsequently, the patterned photoresist layer 30P may be used as a mask in a treatment (such as a doping process illustrated in FIG. 7, but not limited thereto) performed to the semiconductor layer AL for forming the source region SR and the drain region DR. In some embodiments, the dopants used in the doping process described above may include argon (Ar) or other suitable dopants, and the region of the semiconductor layer AL covered by the patterned photoresist layer 30P in the doping process without being influenced by the doping process and/or the region of the semiconductor layer AL covered by the patterned photoresist layer 30P in the doping process which is relatively less affected by the doping process may become the active region CR described above after the doping process, but not limited thereto. By the manufacturing approaches described above, the side surfaces of the active region CR and the side surfaces of the first gate electrode GE1 may be substantially aligned with one another in a self-aligning manner, and the parasitic capacitance between the first gate electrode GE1 and the source region SR and the parasitic capacitance between the first gate electrode GE1 and the drain region DR may be reduced accordingly for improving the operation performance. It is worth noting that the above-mentioned exposure process performed from the back side of the substrate SB and the above-mentioned doping process (such as the condition illustrated in FIG. 7) may be applied to other embodiments of the present disclosure as needed.

After the doping process described above, the patterned photoresist layer 30P may be removed and the step ST6 may be carried out for forming the openings corresponding to the source electrode SE and the drain electrode DE in the insulation layer IN2. In some embodiments, a photolithography and etching process may be performed to the insulation layer IN2 for forming the openings described above, but not limited thereto. Subsequently, the step ST7 may be carried out for forming the electrically conductive layer M2, and the electrically conductive layer M2 may include the source electrode SE, the drain electrode DE, and the bottom electrode BE described above. In some embodiments, an electrically conductive material may be formed on the insulation layer IN2 by a film formation process, the openings formed in the step ST6 described above may be filled with the electrically conductive material, and the electrically conductive material may then be patterned to be the electrically conductive layer M2 by performing a photolithography etching process to this electrically conductive material, but not limited thereto. Subsequently, the step ST8 to the step ST13 may be performed for forming the light-sensing element PD, the protection layer IN3, the protection layer IN4, the protection layer IN5, the electrically conductive layer M3, and the protection layer IN6 sequentially.

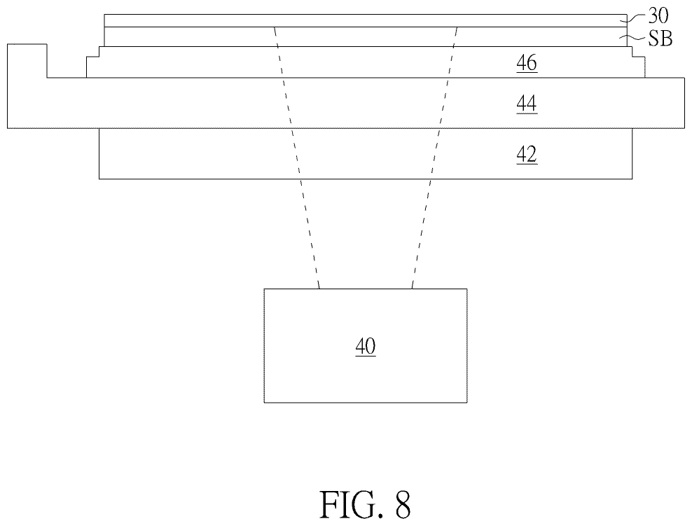

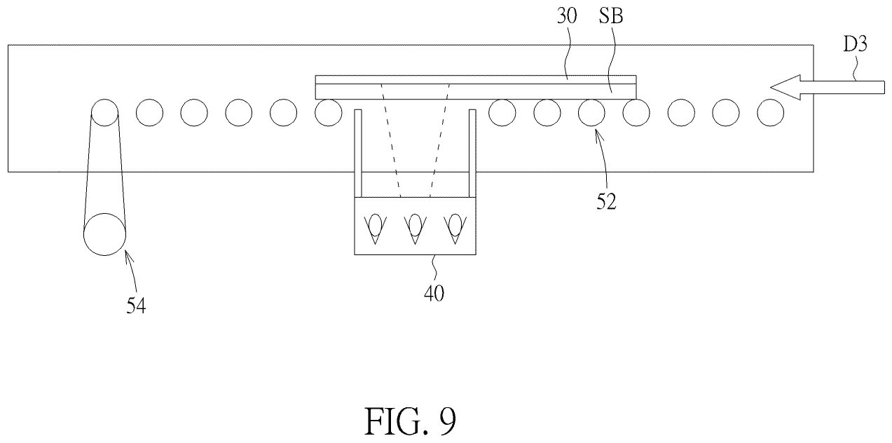

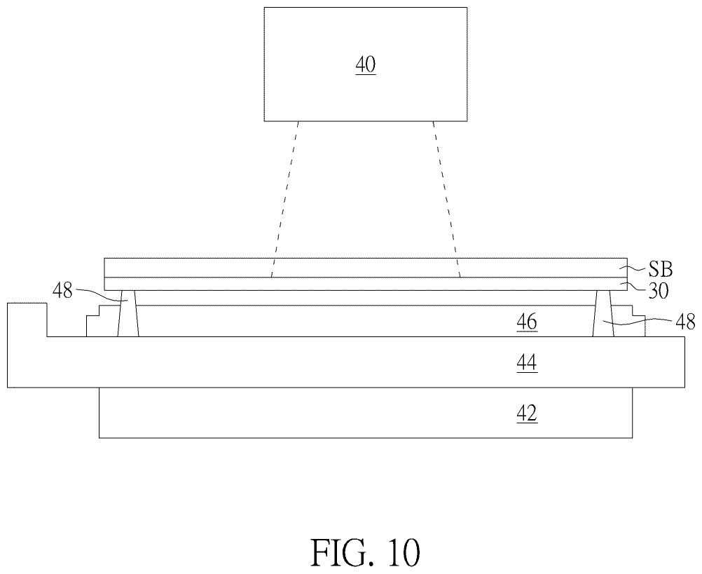

FIG. 8, FIG. 9, and FIG. 10 are schematic diagrams illustrating an exposure process according to different embodiments of the present disclosure. As shown in FIG. 8, in some embodiments, the substrate SB with a photoresist layer 30 formed thereon may be placed on a plate table 44 while the photoresist layer 30 is located at the top side, and the position of substrate SB may be fixed by a holder 46. The substrate SB may be placed on a stage 42 via the plate table 44, and a backside exposure process may be performed to the photoresist layer 30 on the substrate SB by a light source 40 located under the stage 42. As shown in FIG. 9, in some embodiments, the substrate SB with the photoresist layer 30 formed thereon may be placed on a roller 52 while the photoresist layer 30 is located at the top side. The roller 52 rolls via a transmission mechanism 54 so as to transmit the substrate SB in a transmission direction D3, and the substrate SB may be irradiated by the light source 40 underneath the substrate SB for completing the backside exposure process. As shown in FIG. 10, in some embodiments, the substrate SB with the photoresist layer 30 formed thereon may be placed above the plate table 44 while the photoresist layer 30 is located at the bottom side. A support base 48 on the plate table 44 may be used to support the substrate SB, and the position of the support base 48 may be located corresponding to the photoresist layer 30 on a dummy region for avoiding influencing the formation of the patterned photoresist layer. Subsequently, the light source 40 located at the top side may be used to performed the backside exposure process to the photoresist layer 30 on the substrate SB. In the present disclosure, the backside exposure process may be performed to the photoresist layer 30 by the approaches illustrated in FIG. 8, FIG. 9, or FIG. 10 described above, and the above-mentioned patterned photoresist layer (such as the patterned photoresist layer 30P illustrated in FIG. 7, but not limited thereto) may then be formed by carrying out a corresponding developing process. In addition, the method for carrying out the backside exposure process in this disclosure may include but is not limited to the conditions shown in FIGS. 8, 9, and 10, and the backside exposure process may be carried out in other ways as needed.

To summarize the above description, in the thin-film transistor substrate according to the present disclosure, the distance between the side surface of the active region in the semiconductor layer and the side surface of the gate electrode may be controlled for reducing the parasitic capacitance and improving the operation performance. In some embodiments, the patterned photoresist layer may be formed by performing the exposure process from the backside of the substrate with the gate electrode as the mask, and the patterned photoresist layer may be used as a mask in the treatment (such as the doping process, but not limited thereto) performed to the semiconductor layer for forming the source region and the drain region. Accordingly, the side surfaces of the active region and the side surfaces of the gate electrode may be substantially aligned with one another in the self-aligning manner, and the parasitic capacitance between the gate electrode and the source region and the parasitic capacitance between the gate electrode and the drain region may be reduced.

What is claimed is:

1. A thin-film transistor substrate, comprising:
a substrate;
a first gate electrode disposed on the substrate and comprising a first side surface; and
a semiconductor layer disposed on the first gate electrode and comprising an active region,
wherein the active region comprises a second side surface, the second side surface is located adjacent to the first side surface, and a first distance between the first side surface and the second side surface is less than 0.5 micrometer.

2. The thin-film transistor substrate according to claim 1, wherein the first side surface overlaps the second side surface.

3. The thin-film transistor substrate according to claim 1, wherein the first gate electrode further comprises a third side surface opposite to the first side surface, the active region further comprises a fourth side surface opposite to the second side surface, and a second distance between the third side surface and the fourth side surface is less than 0.5 micrometer.

4. The thin-film transistor substrate according to claim 3, wherein the third side surface overlaps the fourth side surface.

5. The thin-film transistor substrate according to claim 3, wherein a difference between the first distance and the second distance is less than 0.5 micrometer.

6. The thin-film transistor substrate according to claim 1, further comprising:
a second gate electrode disposed on the semiconductor layer.

7. The thin-film transistor substrate according to claim 6, wherein a width of the first gate electrode is equal to a width of the second gate electrode.

8. The thin-film transistor substrate according to claim 1, further comprising:
a source electrode and a drain electrode, wherein the source electrode and the drain electrode are disposed on the substrate; and
a light-sensing element electrically connected with the drain electrode.

9. The thin-film transistor substrate according to claim 8, further comprising:
a transparent electrically conductive layer disposed on the light-sensing element, wherein a width of the transparent electrically conductive layer is less than a width of the light-sensing element.

10. The thin-film transistor substrate according to claim 8, wherein an oxygen concentration at a lateral surface of the light-sensing element is higher than an oxygen concentration at a top surface of the light-sensing element and an oxygen concentration at a bottom surface of the light-sensing element, respectively.
